(19) United States
(12) Patent Application Publication
(10) Pub. No.: US 2017/0317217 A1
(43) Pub. Date: Nov. 2, 2017

(54) SEMICONDUCTOR DEVICE AND METHOD FOR MANUFACTURING SAME

(71) Applicant: Sharp Kabushiki Kaisha, Sakai City, Osaka (JP)

(72) Inventors: KAZUATSU ITO, Sakai City (JP); YOHSUKE KANZAKI, Sakai City (JP); TAKAO SAITOH, Sakai City (JP)

(73) Assignee: Sharp Kabushiki Kaisha, Sakai City, Osaka (JP)

(21) Appl. No.: 15/525,942

(22) PCT Filed: Nov. 4, 2015
(86) PCT No.: PCT/JP2015/081012

§ 371 Date: May 10, 2017

(30) Foreign Application Priority Data
Nov. 11, 2014 (JP) 2014-228902

(51) Int. Cl. H01L 29/786; H01L 29/66; H01L 29/49; H01L 29/24; H01L 27/12; H01L 21/44; H01L 21/02

(52) U.S. Cl. CPC H01L 29/78606; H01L 29/7869; H01L 29/78648; H01L 29/66969; H01L 29/4908; H01L 21/0217; H01L 27/1255; H01L 27/1225; H01L 21/44; H01L 21/0234; H01L 29/24

(57) ABSTRACT

Provided is a semiconductor device which has a double-gate structure with a channel layer made of an oxide semiconductor and is capable of inhibiting the occurrence of hysteresis.

A TFT having a double-gate structure with a channel layer 40 made of an oxide semiconductor uses a passivation film (70), which is a film stack obtained by stacking, sequentially from the side closest to the channel layer (40), a silicon oxide film (71), a first silicon nitride film (73), and a second silicon nitride film (74). In this case, the second silicon nitride film (74) farthest from the channel layer (40) is formed so as to have a higher hydrogen content than the first silicon nitride film (73) closer to the channel layer (40). Thus, it is rendered possible to inhibit the shifting of a threshold voltage of the TFT (100) resulting from hydrogen spreading in the channel layer (40), and at the same time, it is also rendered possible to diminish hysteresis and thereby inhibit the shifting of the threshold voltage caused by hysteresis.

### TECHNICAL FIELD

The present invention relates to semiconductor devices and methods for manufacturing the same, particularly to a semiconductor device having a double-gate structure with a channel layer made of an oxide semiconductor and a method for manufacturing the same.

### BACKGROUND ART

Conventionally, channel layers of thin-film transistors (TFTs) used in liquid crystal display devices, organic EL display devices, and the like are formed using silicon semiconductors such as amorphous silicon, polycrystalline silicon, or monocrystalline silicon.

Recent years have seen active development of TFTs using oxide semiconductors, in place of silicon semiconductors, with a view to reducing the leakage current that flows through the TFTs in OFF state. When hydrogen and nitrogen spread in such an oxide semiconductor, these substances become sources of carrier generation, leading to a shift in TFT threshold voltage.

Therefore, Patent Document 1 discloses that, to inhibit hydrogen and nitrogen included in large amounts in a silicon nitride (SiNx) film, which is used for a passivation film, from spreading in a channel layer made of an oxide semiconductor, the densities of hydrogen and nitrogen in the silicon nitride film included in the passivation film are adjusted to be less than or equal to predetermined values or lower.

### CITATION LIST

### Patent Document

Patent Document 1: Japanese Laid-Open Patent Publication No. 2014-30002

### SUMMARY OF THE INVENTION

### Problems to be Solved by the Invention

However, in the case of the TFT that has a double-gate structure with a channel layer made of an oxide semiconductor, even if the densities of hydrogen and nitrogen contained in the passivation film are adjusted to be less than or equal to predetermined values, drain current values, which correspond to voltages applied to top and bottom gates, change depending on whether the voltages are raised or lowered. Such a phenomenon is called hysteresis.

FIG. 14 is a graph showing Vg-Id characteristics which represent the relationship between gate voltage and drain current where a TFT is driven by applying the same gate voltage to bottom- and top-gate electrodes of the TFT. As shown in FIG. 14, when the gate voltage Vg is raised from 0V to 30V (solid line) and thereafter lowered to about 8V (dotted line), the drain current Id becomes almost equal to the value where the gate voltage Vg is 0V, i.e., the voltage value before the raise, and thereafter, the drain current Id remains the same even if the gate voltage Vg is further lowered. In this manner, simply by raising and lowering the gate voltage Vg once, the gate voltage Vg that corresponds to the same drain current Id changes about 8V, and the TFT exhibits a significant hysteresis. In this case, the magnitude of the hysteresis is 8V.

FIG. 15 is a graph showing the hysteresis of the TFT where the gate voltage is further raised and lowered repeatedly. As shown in FIG. 15, when the gate voltage Vg is raised and lowered (i.e., voltage sweep is performed) multiple times, the amount of change in gate voltage Vg, i.e., the amount of change in hysteresis, decreases as the number of sweeps increases, for example, such that the amount of change is 8V at the first sweep, 5V at the second sweep, and 3V at the third sweep. However, hysteresis occurs every sweep, and the threshold voltage of the TFT correspondingly shifts little by little toward the positive end.

In the case where a TFT with a significant hysteresis is used as a switching transistor for each pixel of a liquid crystal display device, the threshold voltage of the TFT shifts every time the TFT is rendered in ON state by applying a voltage of 20V to a gate electrode. As a result, the drain current value of the TFT changes, so that the state of charge in a liquid crystal capacitor connected to the TFT changes, and the state of a display image changes correspondingly. In this manner, the TFT that has a double-gate structure with a channel layer made of an oxide semiconductor has a problem with the shifting of the TFT threshold voltage resulting from the hysteresis increasing by raising and lowering the gate voltage.

Therefore, an objective of the present invention is to provide a semiconductor device which has a double-gate structure with a channel layer made of an oxide semiconductor and is capable of inhibiting the occurrence of hysteresis, as well as a method for manufacturing the same.

### Means for Solving the Problems

A first aspect of the present invention is directed to a semiconductor device including:
a bottom-gate electrode formed on a substrate;
a gate insulating film formed on the bottom-gate electrode;
a channel layer overlying a part of the bottom-gate electrode with the gate insulating film intervening therebetween;
source and drain conductors electrically connected to the channel layer;
a protective film formed on the channel layer; and
a top-gate electrode formed on the protective film so as to be positioned opposite the bottom-gate electrode, wherein,
either the gate insulating film or the protective film, or both, includes a nitride insulating region made of one or more nitride insulating films, and
the nitride insulating region is formed such that hydrogen content increases with the distance from the channel layer.

A second aspect of the present invention provides the semiconductor device according to the first aspect of the present invention, wherein the nitride insulating region included in the protective film is a film stack obtained by stacking at least two of the nitride insulating films containing hydrogen such that the hydrogen contained in the nitride insulating films increases with the distance from the channel layer.

A third aspect of the present invention provides the semiconductor device according to the first aspect of the present invention, wherein the nitride insulating region included in the protective film includes a single-layer nitride insulating film containing hydrogen and being formed such that the contained hydrogen increases with the distance from the channel layer.

A fourth aspect of the present invention provides the semiconductor device according to the second or third aspect of the present invention, wherein the protective film further includes an oxide insulating film disposed between the channel layer and the film stack or the single-layer nitride insulating film.

A fifth aspect of the present invention provides the semiconductor device according to the first aspect of the present invention, wherein the nitride insulating region included in the gate insulating film is a film stack obtained by stacking at least two of the nitride insulating films containing hydrogen such that the hydrogen contained in the nitride insulating films increases with the distance from the channel layer.

A sixth aspect of the present invention provides the semiconductor device according to the first aspect of the present invention, wherein the nitride insulating region included in the gate insulating film includes a single-layer nitride insulating film containing hydrogen and being formed such that the contained hydrogen increases with the distance from the channel layer.

A seventh aspect of the present invention provides the semiconductor device according to the fifth or sixth aspect of the present invention, wherein the gate insulating film further includes an oxide insulating film disposed between the channel layer and the film stack or the single-layer nitride insulating film.

An eighth aspect of the present invention provides the semiconductor device according to the first aspect of the present invention, wherein the channel layer includes an oxide semiconductor.

A ninth aspect of the present invention provides the semiconductor device according to the eighth aspect of the present invention, wherein the oxide semiconductor is indium gallium zinc oxide.

A tenth aspect of the present invention provides the semiconductor device according to the ninth aspect of the present invention, wherein the indium gallium zinc oxide is crystalline.

An eleventh aspect of the present invention provides the semiconductor device according to the second through fifth aspects of the present invention, wherein the nitride insulating film is a silicon nitride film or a silicon oxynitride film.

A twelfth aspect of the present invention provides the semiconductor device according to the fourth or seventh aspect of the present invention, wherein the oxide insulating film is a silicon oxide film.

A thirteenth aspect of the present invention provides the semiconductor device according to the second or fifth aspect of the present invention, wherein the nitride insulating region is a stack of a first silicon nitride film disposed on a side proximal to the channel layer and a second silicon nitride film disposed on a side distal to the channel layer and emitting more hydrogen molecules than the first silicon nitride film.

A fourteenth aspect of the present invention provides the semiconductor device according to the thirteenth aspect of the present invention, wherein the amount of hydrogen molecule emission as measured by thermal desorption spectroscopy is less than 5×10²¹ molecules/cm³ for the first silicon nitride film and 5×10²¹ molecules/cm³ or more for the second silicon nitride film.

A fifteenth aspect of the present invention provides the semiconductor device according to the first aspect of the present invention, further including a capacitance element including a first electrode, a second electrode electrically connected to the drain conductor, and an insulating layer provided between the first and second electrodes, wherein,
the nitride insulating region included in the protective film is a stack of a first silicon nitride film disposed on a side proximal to the channel layer and a second silicon nitride film disposed on a side distal to the channel layer and containing more hydrogen than the first silicon nitride film, and
the insulating layer is a film simultaneously formed with the second silicon nitride film included in the protective film.

A sixteenth aspect of the present invention provides a method for manufacturing a semiconductor device including a bottom-gate electrode formed on a substrate, a gate insulating film formed on the bottom-gate electrode, a channel layer overlying a part of the bottom-gate electrode with the gate insulating film intervening therebetween, source and drain conductors electrically connected to the channel layer, a protective film formed on the channel layer, and a top-gate electrode formed on the protective film so as to be positioned opposite the bottom-gate electrode, wherein,
the gate insulating film includes first and second silicon nitride films containing hydrogen, the first silicon nitride film being formed on the second silicon nitride film and containing less hydrogen than the second silicon nitride film, and
the method includes a plasma treatment step for performing hydrogen plasma treatment on a surface of the second silicon nitride film after the formation of the second silicon nitride film but before the formation of the first silicon nitride film.

A seventeenth aspect of the present invention provides a method for manufacturing a semiconductor device including a bottom-gate electrode formed on a substrate, a gate insulating film formed on the bottom-gate electrode, a channel layer overlying a part of the bottom-gate electrode with the gate insulating film intervening therebetween, source and drain conductors electrically connected to the channel layer, a protective film formed on the channel layer, and a top-gate electrode formed on the protective film so as to be positioned opposite the bottom-gate electrode, wherein,
the protective film includes a first silicon nitride film containing hydrogen and a second silicon nitride film formed on the first silicon nitride film and containing more hydrogen than the first silicon nitride film, and
the method comprises a plasma treatment step for performing hydrogen plasma treatment on a surface of the second silicon nitride film after the formation of the second silicon nitride film but before the formation of the top-gate electrode.

### Effect of the Invention

In the first aspect of the present invention, the semiconductor device has a double-gate structure with the channel layer made of an oxide semiconductor, and also has the gate insulating film and the protective film, at least one of which is the nitride insulating region that is formed of one or more nitride insulating films such that contained hydrogen increases with the distance from the channel layer. Thus, hysteresis is diminished so that the shifting of the threshold voltage caused by hydrogen can be inhibited. Moreover, in the case where such a semiconductor device is used as a switching element for a pixel of a display device, constant image display quality is maintained, and in the case where the semiconductor device is used as a TFT included in a peripheral circuit, such as a source or gate driver, of a display device, the malfunctioning of the peripheral circuit is reduced.

In the second aspect of the present invention, the protective film includes the film stack obtained by stacking the nitride insulating films containing hydrogen, and the hydrogen contained in the nitride insulating films increases with the distance from the channel layer, and therefore, effects similar to those achieved by the first aspect of the invention can be achieved.

In the third aspect of the present invention, the protective film includes the single-layer nitride insulating film being formed such that contained hydrogen increases with the distance from the channel layer, and therefore, effects similar to those achieved by the first aspect of the invention can be achieved.

In the fourth aspect of the present invention, the protective film includes the oxide insulating film disposed between the channel layer and the film stack or the single-layer nitride insulating film, so that the hydrogen contained in the nitride insulating film is less likely to spread in the channel layer. Thus, the threshold voltage of the semiconductor device is inhibited from being shifted.

In the fifth aspect of the present invention, the gate insulating film includes the film stack obtained by stacking the nitride insulating films such that contained hydrogen increases with the distance from the channel layer, and therefore, effects similar to those achieved by the first aspect of the invention can be achieved.

In the sixth aspect of the present invention, the gate insulating film includes the single-layer nitride insulating film being formed such that contained hydrogen increases with the distance from the channel layer, and therefore, effects similar to those achieved by the first aspect of the invention can be achieved.

In the seventh aspect of the present invention, the gate insulating film includes the oxide insulating film disposed between the channel layer and the film stack or the single-layer nitride insulating film, so that the hydrogen contained in the nitride insulating film is less likely to spread in the channel layer. Thus, the threshold voltage of the semiconductor device is inhibited from being shifted.

In the eighth aspect of the present invention, the channel layer includes the oxide semiconductor layer, so that the leakage current of the semiconductor device can be reduced.

In the ninth aspect of the present invention, the oxide semiconductor is indium gallium zinc oxide, and therefore, effects similar to those achieved by the eighth aspect of the invention can be achieved.

In the tenth aspect of the present invention, the indium gallium zinc oxide is crystalline, whereby the threshold voltage of the semiconductor device can be kept from varying, resulting in stable characteristics, and the quantity of mobile ions in the gate insulating film is decreased, with the result that high reliability can be secured.

In the eleventh aspect of the present invention, the nitride insulating film is a silicon nitride film, and therefore, effects similar to those achieved by the first aspect of the invention can be achieved.

In the twelfth aspect of the present invention, the oxide insulating film is a silicon oxide film, and therefore, effects similar to those achieved by the fourth or seventh aspect of the invention can be achieved.

In the thirteenth aspect of the present invention, of the first and second silicon nitrides, which form the nitride insulating region, the second silicon nitride film disposed distal to the channel layer emits more hydrogen molecules than the first silicon nitride film disposed proximal to the channel layer, and therefore, effects similar to those achieved by the first aspect of the invention can be achieved.

In the fourteenth aspect of the present invention, the amount of hydrogen molecule emission from the first silicon nitride film is less than 5×10²¹ molecules/cm³, and the amount of hydrogen molecule emission from the second silicon nitride film is 5×10²¹ molecules/cm³ or more.

In the fifteenth aspect of the present invention, the insulating layer of the capacitance element electrically connected to the semiconductor device is formed simultaneously with the second silicon nitride film included in the protective film of the semiconductor device, whereby the process for manufacturing the semiconductor device including the capacitance element can be simplified.

In the sixteenth aspect of the present invention, hydrogen plasma treatment is performed on the surface of the second silicon nitride film included in the gate insulating film after the formation of the second silicon nitride film but before the formation of the first silicon nitride film. As a result, the hydrogen content of the second silicon nitride film can be increased around the surface, resulting in a diminished hysteresis of the semiconductor device. Thus, it is possible to inhibit the shifting of the threshold voltage caused by hysteresis.

In the seventeenth aspect of the present invention, hydrogen plasma treatment is performed on the surface of the second silicon nitride film included in the protective film after the formation of the second silicon nitride film but before the formation of the top-gate electrode. As a result, the hydrogen content of the second silicon nitride film can be increased around the surface, resulting in a diminished hysteresis of the semiconductor device. Thus, it is possible to inhibit the shifting of the threshold voltage caused by hysteresis.

### BRIEF DESCRIPTION OF THE DRAWINGS

FIG. 1 provides a top view and a cross-sectional view illustrating the structure of a TFT according to a first embodiment of the present invention; more specifically, part (A) is the top view of the TFT, and part (B) is the cross-sectional view of the TFT taken along long-dash dot line A-A′ shown in part (A).

FIG. 2 provides an enlarged cross-sectional view illustrating the structure of a passivation film in the TFT shown in FIG. 1.

FIG. 3 is a graph showing the relationship between the amount of hydrogen emission from a silicon nitride film and the threshold-voltage shift amount of the TFT.

FIG. 4 is a graph showing the relationship between the amount of hydrogen emission from the silicon nitride film and the magnitude of hysteresis of the TFT.

FIG. 5 is a graph showing Vg-Id characteristics where the hydrogen contents in first and second silicon nitride films of the TFT shown in FIG. 1 are adjusted.

FIGS. 6(A) to 6(C) are cross-sectional views illustrating the process for manufacturing the TFT shown in FIG. 1.

FIGS. 7(A) to (C) are cross-sectional views continued from FIG. 6 illustrating the process for manufacturing the TFT.

FIG. 8 provides an enlarged cross-sectional view of a passivation film where a first silicon nitride film shown in the enlarged cross-sectional view in FIG. 2 consists of two separate layers.

FIG. 9 provides a cross-sectional view illustrating the structure of a passivation film including a silicon nitride film whose hydrogen content changes continuously in the TFT shown in FIG. 1.

FIGS. 10(A) and 10(B) are views illustrating the process for manufacturing a TFT and a liquid crystal capacitor in a fourth variant of the first embodiment.

FIGS. 11(A) and 10(B) are views continued from FIG. 10 illustrating the process for manufacturing the TFT and the liquid crystal capacitor in the fourth variant of the embodiment.

FIG. 12 provides an enlarged cross-sectional view illustrating the structure of a gate insulating film in a TFT according to a second embodiment of the present invention.

FIG. 13 provides enlarged cross-sectional views illustrating the structures of a gate insulating film and a passivation film in a TFT according to a third embodiment of the present invention.

FIG. 14 is a graph showing Vg-Id characteristics which represent the relationship between gate voltage and drain current where a conventional TFT is driven by applying the same voltage to bottom and top gates.

FIG. 15 is a graph showing the hysteresis of the conventional TFT where the gate voltage is raised and lowered repeatedly.

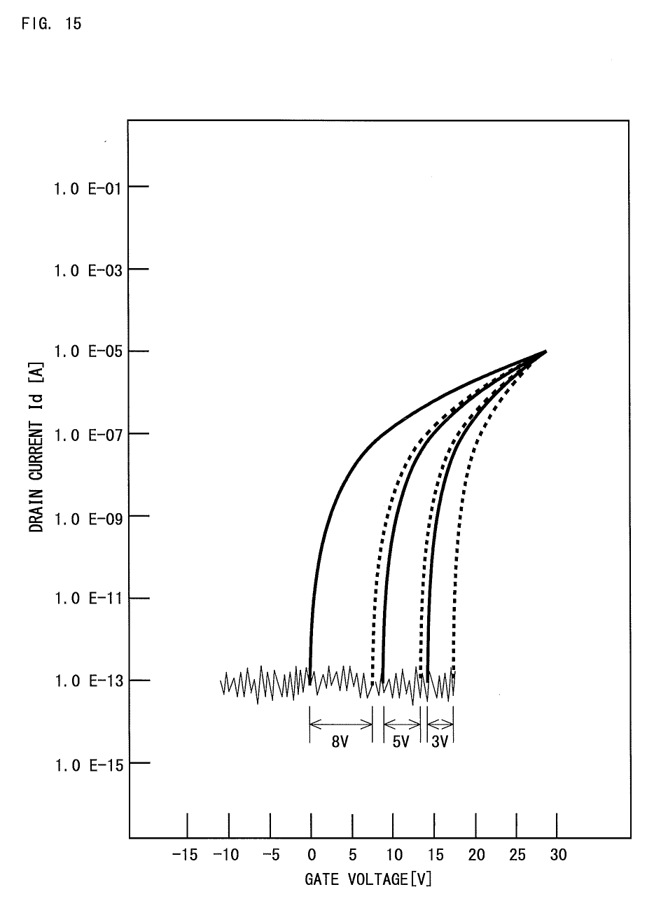

### MODES FOR CARRYING OUT THE INVENTION

### 1. First Embodiment

The structure of a TFT according to a first embodiment of the present invention, along with a method for manufacturing the TFT, will be described with reference to the drawings.

### <1.1 Structure of the TFT>

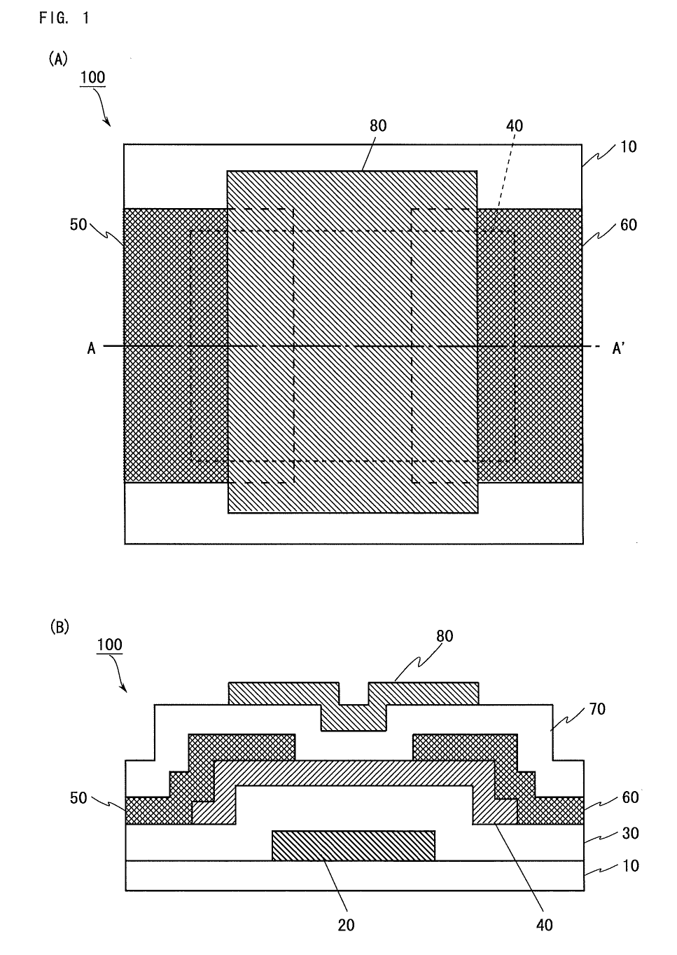

FIG. 1 provides a top view and a cross-sectional view illustrating the structure of the TFT 100 according to the first embodiment of the present invention; more specifically, FIG. 1(A) is the top view of the TFT 100, and FIG. 1(B) is the cross-sectional view of the TFT 100 taken along long-dash dot line A-A′ shown in FIG. 1(A). Note that in FIG. 1(A), a gate insulating film 30 and a passivation film 70 shown in FIG. 1(B) are omitted for the sake of clarity.

As shown in FIGS. 1(A) and 1(B), there is a bottom-gate electrode 20 formed on a substrate 10 such as a glass substrate. The bottom-gate electrode 20 is a film stack obtained by stacking, sequentially from the substrate 10 side, a titanium (Ti) film with a thickness of from 40 to 60 nm, an aluminum (Al) film with a thickness of from 150 to 250 nm, and a titanium film with a thickness of from 40 to 60 nm. Note that the bottom-gate electrode 20 may be a film stack obtained by stacking, sequentially from the substrate 10 side, a tantalum (Ta) film with a thickness of from 40 to 60 nm and a tungsten (W) film with a thickness of from 350 to 450 nm, a single-layer film made of titanium, molybdenum (Mo), tantalum, tungsten, or copper (Cu), an alloy film of such single-layer films, or a film stack obtained by stacking some of the single-layer films.

Provided on the bottom-gate electrode 20 is the gate insulating film 30. The gate insulating film 30 is a film stack obtained by stacking, from the bottom-gate electrode 20 side, a silicon nitride (SiNx) film with a thickness of from 300 to 400 nm and a silicon oxide (SiO₂) film with a thickness of from 40 to 60 nm. Alternatively, in place of the silicon nitride film included in the film stack, a silicon oxynitride film (SiONx) film may be stacked.

Provided on the gate insulating film 30 is a channel layer 40 in the shape of a rectangle stretching beyond opposite sides of the bottom-gate electrode 20 in the right-left direction in FIG. 1(B). The channel layer 40 is made of an oxide semiconductor, e.g., an In—Ga—Zn—O based semiconductor with a thickness of 100 nm. The In—Ga—Zn—O based semiconductor included in this oxide semiconductor layer is a ternary oxide of indium (In), gallium (Ga), and zinc (Zn), and non-limiting examples of the ratio (composition ratio) among indium, gallium, and zinc include In:Ga:Zn=2:2:1, In:Ga:Zn=1:1:1, and In:Ga:Zn=1:1:2. Herein, the In—Ga—Zn—O based semiconductor used as the oxide semiconductor contains In, Ga, and Zn at a ratio of 1:1:1.

The TFT 100, which includes the channel layer 40 made of the In—Ga—Zn—O based semiconductor, exhibits characteristics with high mobility (more than 20 times the mobility of a-Si TFTs) and low leakage current (less than 1/100 of the leakage current of a-TFTs), and therefore can be suitably used as a drive TFT included in a source or gate driver of a display device or a pixel TFT serving as a switching element of each pixel. By using the TFT 100 with the channel layer 40 made of the In—Ga—Zn—O based semiconductor for a display device, it is rendered possible to significantly reduce power consumption of the display device.

The In—Ga—Zn—O based semiconductor may be amorphous or may be crystalline as a result of including crystalline portions. Such a crystalline In—Ga—Zn—O based semiconductor preferably has a c-axis oriented substantially vertically to the layer surface. The crystal structure of such a crystalline In—Ga—Zn—O based semiconductor is disclosed in, for example, Japanese Laid-Open Patent Publication No. 2012-134475.

The disclosure of Japanese Laid-Open Patent Publication No. 2012-134475 is incorporated herein by reference in its entirety. In this manner, the TFT 100, which uses the crystalline In—Ga—Zn—O based material for the channel layer 40, renders it possible to inhibit variations in threshold voltage, thereby stabilizing characteristics, and also to reduce the quantity of mobile ions in the gate insulating film, thereby ensuring high reliability.

The oxide semiconductor may be an oxide semiconductor other than the In—Ga—Zn—O based semiconductor. Examples of such an oxide semiconductor include a Zn—O based semiconductor (ZnO), an In—Zn—O based semiconductor (IZO (registered trademark)), a Zn—Ti—O based semiconductor (ZTO), a Cd—Ge—O based semiconductor, a Cd—Pb—O based semiconductor, a CdO (cadmium oxide), an Mg—Zn—O based semiconductor, an In—Sn—Zn—O based semiconductor (e.g., In₂O₃—SnO₂—ZnO), and an In—Ga—Sn—O based semiconductor.

Formed on the channel layer 40 are a source conductor 50 and a drain conductor 60 in the shape of rectangles extending from opposite sides of the channel layer 40 in the channel-length direction so as to be away from each other (in the right-left direction in FIG. 1(B)). As shown in FIG. 1(B), the source conductor 50 is formed so as to extend leftward beyond the top-left portion of the channel layer 40, and the drain conductor 60 is formed so as to extend rightward beyond the top-right portion of the channel layer 40. As with the bottom-gate electrode 20, the source conductor 50 and the drain conductor 60 are film stacks, each being obtained by stacking, sequentially from the channel layer 40 side, a titanium film with a thickness of from 40 to 60 nm, an aluminum film with a thickness of from 150 to 250 nm, and a titanium film with a thickness of from 40 to 60 nm. Note that the source conductor 50 and the drain conductor 60 may be single-layer films, each being made of titanium, molybdenum, tantalum, tungsten, or copper, alloy films of such single-layer films, or stacks obtained by stacking some of the single-layer films.

Formed on the source conductor 50, the drain conductor 60, and a portion of the channel layer 40 that is not covered by these conductors is the passivation film 70. The passivation film 70 is a film stack in which two silicon nitride films (not shown) with different hydrogen contents are stacked on a silicon oxide film (not shown). More specifically, one of the two silicon nitride films is a first silicon nitride film formed on the silicon oxide film and having a low hydrogen content, and the other is a second silicon nitride film formed on the first silicon nitride film and having a high hydrogen content. The thickness of each film included in the passivation film is, for example, such that the silicon oxide film has a thickness of from 200 to 400 nm, the first silicon nitride film has a thickness of from 100 to 200 nm, and the second silicon nitride film has a thickness of from 100 to 200 nm. Note that the hydrogen content of each of the first and second silicon nitride films will be described later. The passivation film 70 will also be referred to herein as the “protective film”.

Provided on the passivation film 70 is a top-gate electrode 80 in a position above the channel layer 40 sandwiched between the source conductor 50 and the drain conductor 60. More specifically, the top-gate electrode 80 is formed opposite the bottom-gate electrode 20 with the gate insulating film 30, the channel layer 40, and the passivation film 70 positioned therebetween. Note that the top-gate electrode 80 is made of IZO, which is an oxide conductor.

### <1.2 Hydrogen Content in the Passivation Film>

Described first is a method for evaluating the hydrogen content in the silicon nitride film. As a source gas for use in forming a silicon nitride film, silane (SiH₄) and ammonia (NH₃) gases, which contain an abundance of hydrogen, are used.

The hydrogen contained in these gases is thought to be included in part as hydrogen molecules, radicals, or ions in the formed silicon nitride film, but details remain unknown. Accordingly, the substance contained in the silicon nitride film is assumed herein to be “hydrogen”.

In the present invention, the hydrogen content in the silicon nitride film is evaluated by thermal desorption spectroscopy (TDS). In TDS, a sample (in the present embodiment, a silicon nitride film) is irradiated with infrared light in a vacuum, thereby raising the temperature of the sample from 80° C. to 700° C. at a rate of 1° C./sec, and the partial pressure of hydrogen gas desorbed from the sample is measured using a quadrupole mass spectrometer (QMS). The partial pressure of hydrogen gas obtained by the QMS is converted to the number of hydrogen molecules in accordance with a known relational expression. The number of hydrogen molecules thus obtained is considered as the amount of hydrogen emission from the sample. Note that herein, the amount of hydrogen emission from the silicon nitride film is measured using a “TDS 1200” system manufactured by ESCO, Ltd. The amount of hydrogen emission from the silicon nitride film thus measured can be conceived to be substantially proportional to the hydrogen content in the silicon nitride film, and therefore can be used as an indication of the hydrogen content.

The effect of the hydrogen content in the passivation film on the electrical characteristics of the TFT will be described. Silane (SiH₄) gas is used for forming the silicon nitride film that serves as the passivation film 70, as will be described later, and therefore, the silicon nitride film contains an abundance of hydrogen, which is a component of the silane gas. When hydrogen spreads in the channel layer, carriers are generated, with the result that the threshold voltage of the TFT is shifted. Accordingly, the silicon oxide film is provided between the channel layer and the silicon nitride film in order to keep the silicon nitride film from directly contacting the channel layer, thereby inhibiting hydrogen from spreading into the channel layer.

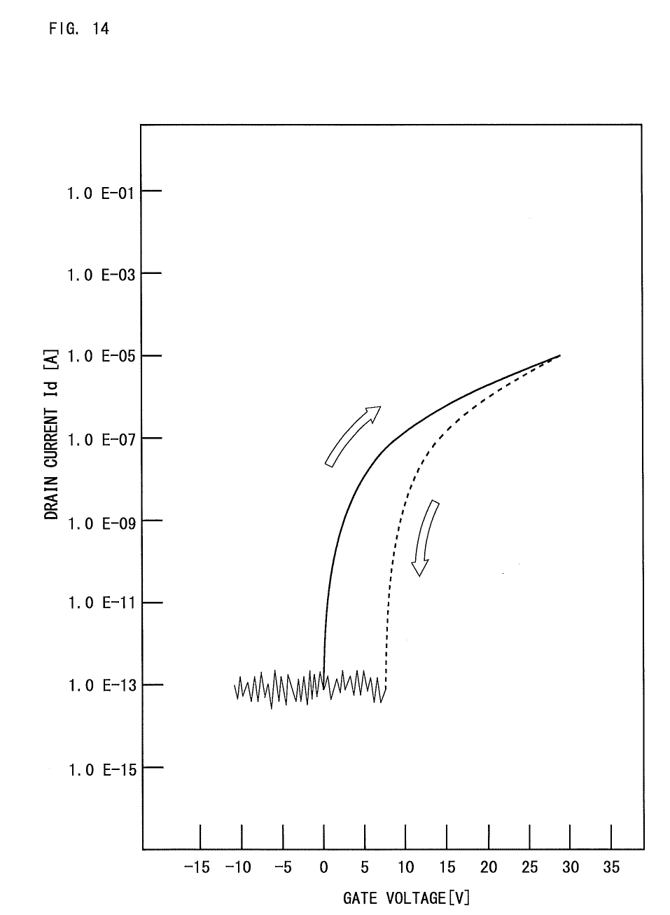

The hydrogen content of the silicon nitride film is preferably low because the lower the hydrogen content is, the less likely hydrogen is to spread from the silicon nitride film into the channel layer, with the result that the threshold voltage of the TFT is inhibited from being shifted. However, in contrast, if the hydrogen content of the silicon nitride film is excessively low, there is a problem where hysteresis becomes significant, as shown in FIG. 14.

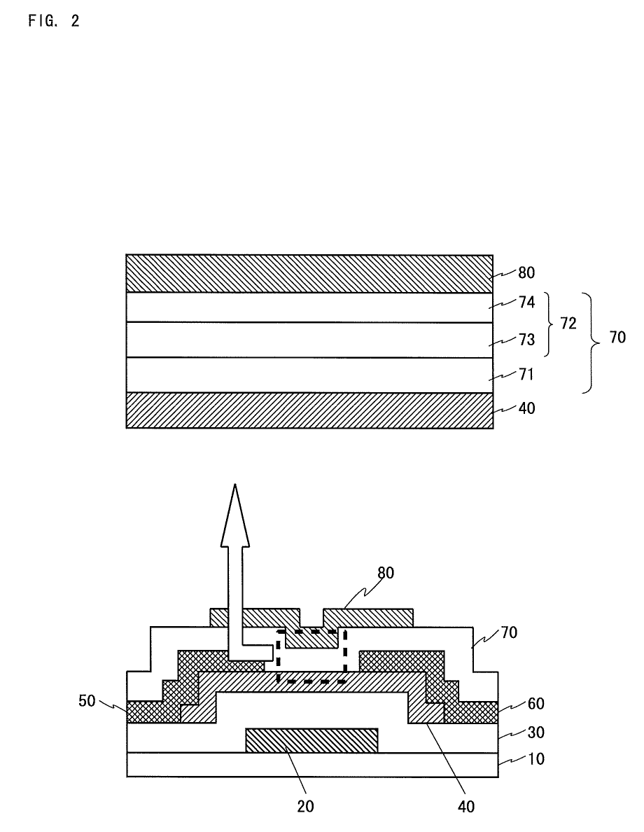

Therefore, the hydrogen content of the silicon nitride film is set as below. FIG. 2 provides an enlarged cross-sectional view illustrating the structure of the passivation film 70 in the present embodiment. Specifically, the enlarged cross-sectional view shown in FIG. 2 corresponds to a portion of the TFT depicted within a rectangle in the lower part of FIG. 2. As shown in FIG. 2, the passivation film 70 sandwiched between the channel layer 40 and the top-gate electrode 80 consists of a silicon oxide film 71 and a silicon nitride film 72, which are sequentially stacked from the channel layer 40 side. In addition, the silicon nitride film 72 consists of a first silicon nitride film 73 proximal to the channel layer 40 and a second silicon nitride film 74 formed on the outside with respect to the first silicon nitride film 73. Note that the silicon nitride film 72 will also be referred to herein as the “nitride insulating region”.

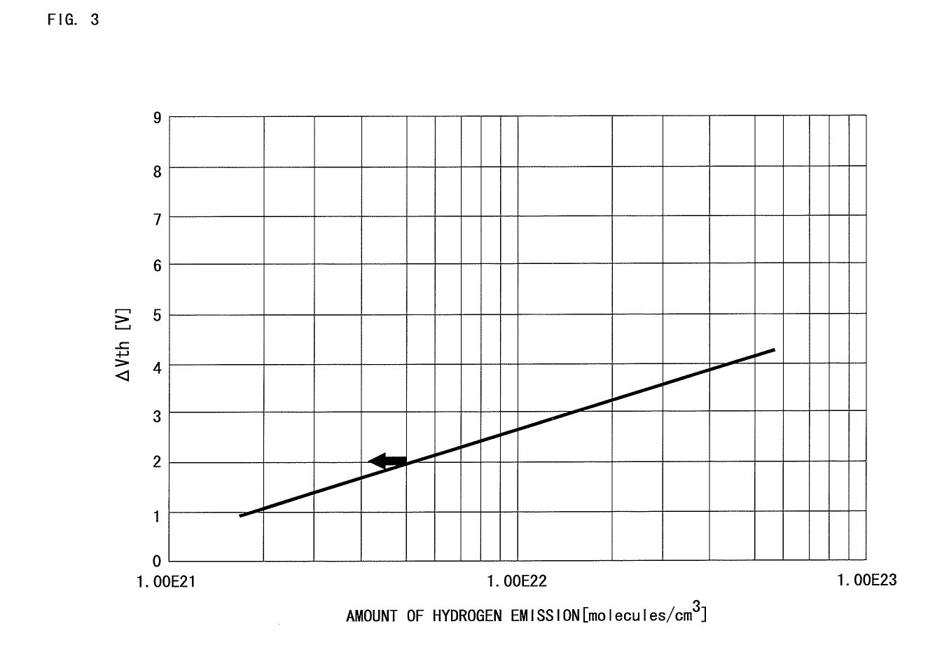

Discussed first is the hydrogen content of the first silicon nitride film 73. FIG. 3 is a graph showing the relationship between the amount of hydrogen emission from the silicon nitride film and the threshold-voltage shift amount ΔVth of the TFT. Note that the threshold-voltage shift amount ΔVth is an amount of change obtained by comparing threshold voltages before and after one-hour application of a 30V voltage to the bottom-gate electrode 20 and the top-gate electrode 80 in a dark room at a temperature of 60° C. From FIG. 3, it can be appreciated that, to decrease the threshold-voltage shift amount ΔVth, the hydrogen content of the first silicon nitride film 73 needs to be reduced. For example, in order to decrease the threshold-voltage shift amount ΔVth of the TFT to 2V or less, the hydrogen content of the first silicon nitride film 73 needs to be less than 5×10²¹ molecules/cm³. This reduces the amount of hydrogen that spreads from the first silicon nitride film 73 proximal to the channel layer 40 into the channel layer 40 through the silicon oxide film 71. On the other hand, the amount of hydrogen emission from the first silicon nitride film 73 needs to be at least 5×10²⁰ molecules/cm³. The reason for this is that when the amount of hydrogen emission is less than 5×10²⁰ molecules/cm³, the threshold voltage varies greatly among TFTs 100 formed on the substrate 10.

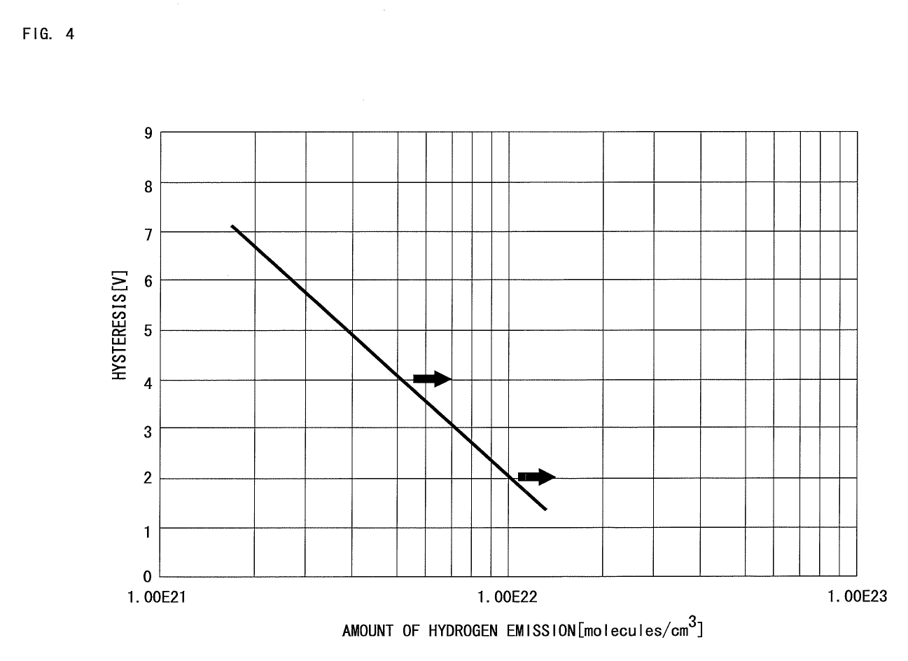

Discussed next is the hydrogen content of the second silicon nitride film 74. FIG. 4 is a graph showing the relationship between the amount of hydrogen emission from the silicon nitride film and the magnitude of hysteresis of the TFT. Note that the magnitude of hysteresis is represented by the amount of change in gate voltage for which the same drain current value as the value measured before the raising of the gate voltage is obtained where the gate voltage is raised and lowered between 0V and 30V. From FIG. 4, it can be appreciated that, to diminish hysteresis, it is simply required to increase the hydrogen content of the second silicon nitride film 74. Accordingly, to reduce the magnitude of hysteresis to 4V or less, the hydrogen content of the second silicon nitride film 74 is increased to 5×10²¹ molecules/cm³ or more. Further, it is preferable to reduce the magnitude of hysteresis to 2V or less, and in such a case, the hydrogen content is increased to 1×10²² molecules/cm³ or more. On the other hand, the amount of hydrogen emission from the second silicon nitride film 74 needs to be 5×10²² molecules/cm³ or less. The reason for this is that, if the amount of hydrogen emission is more than 5×10²² molecules/cm³, hydrogen spreads in the silicon nitride film 74 with low hydrogen content, whereby carriers are generated, with the result that the threshold voltage of the TFT 100 is shifted.

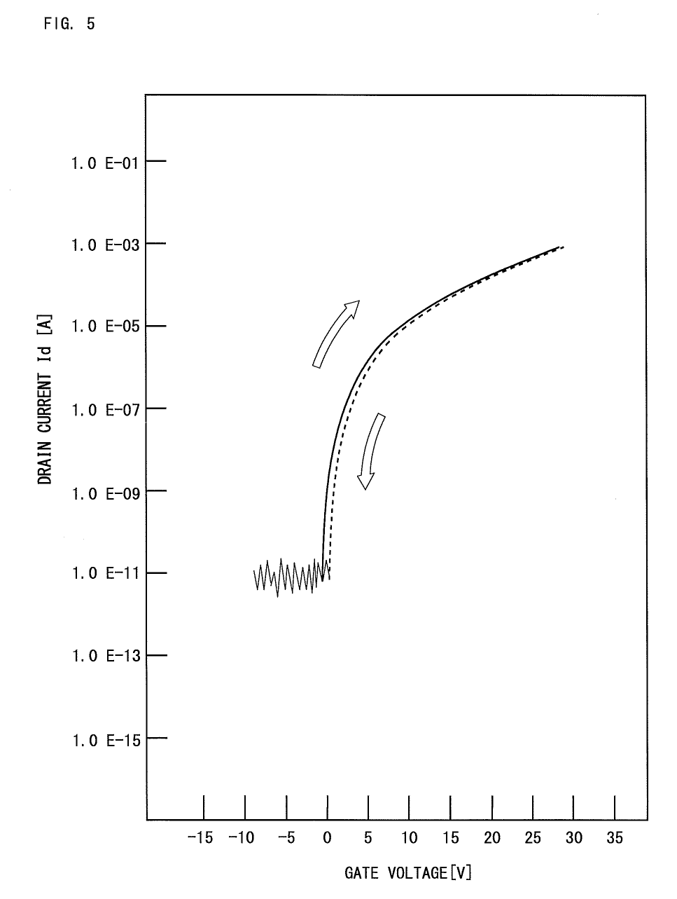

FIG. 5 is a graph showing Vg-Id characteristics where the hydrogen contents in the first and second silicon nitride films 73 and 74 are adjusted. As shown in FIG. 5, when the gate voltage is raised and lowered between 0V and 30V, the characteristic curve for the raising and the characteristic curve for the lowering almost overlap, unlike in the aforementioned case in FIG. 14, and therefore, it can be appreciated that there is a significant improvement in hysteresis.

In this manner, the silicon nitride film 72 in the passivation film 70 consists of two separate layers, such that the second silicon nitride film 74 distal to the channel layer 40 has a higher hydrogen content than the first silicon nitride film 73 proximal to the channel layer 40, whereby the hysteresis of the TFT 100 can be diminished. In addition, the hydrogen content of the first silicon nitride film 73 is set at less than 5×10²¹ molecules/cm³, and the hydrogen content of the second silicon nitride film 74 is set at 5×10²¹ molecules/cm³ or higher, more preferably, 1×10²² molecules/cm³ or higher, whereby the hysteresis of the TFT 100 can be further diminished.

### <1.3 Method for Manufacturing the TFT>

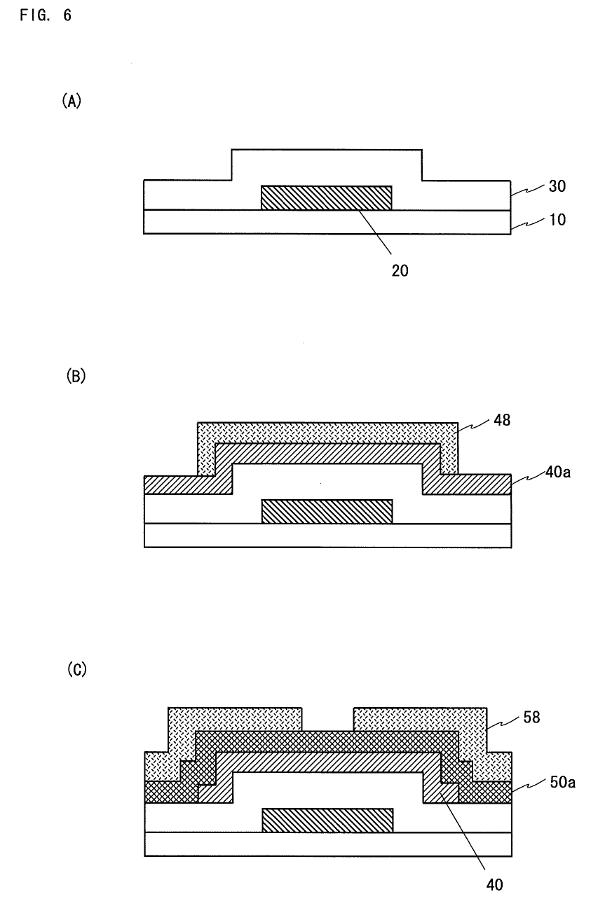

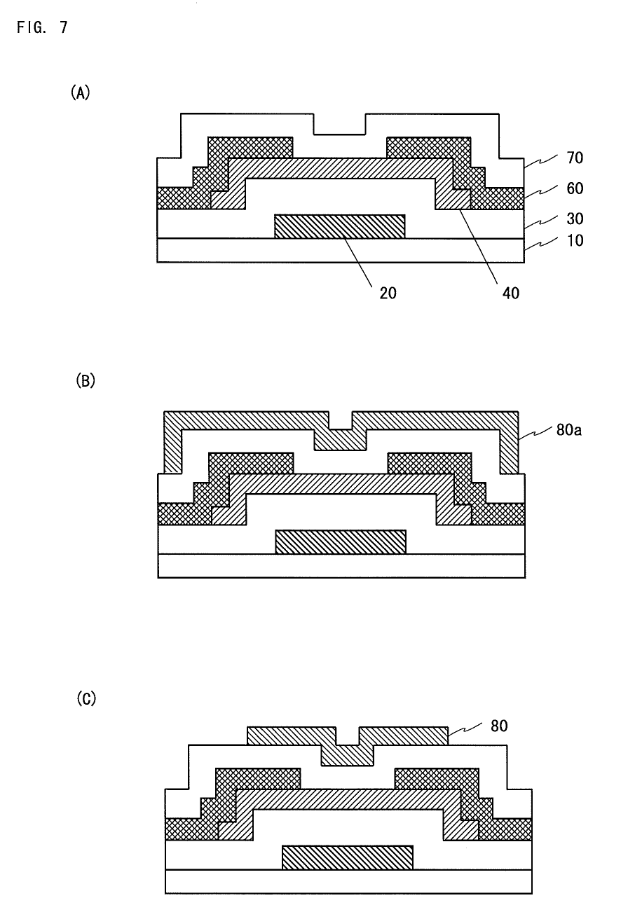

FIGS. 6(A) to 6(C) and 7(A) to 7(C) are cross-sectional views illustrating the process for manufacturing the TFT 100. Referring to the cross-sectional views, the method for manufacturing the TFT 100 will be described. As shown in FIG. 6(A), a titanium film with a thickness of from 40 to 60 nm, an aluminum film with a thickness of from 150 to 250 nm, and another titanium film with a thickness of from 40 to 60 nm are sequentially formed over a substrate 10 by sputtering. Next, on the upper titanium film, a resist pattern is formed by photolithography, and the titanium film, the aluminum film, and the lower titanium film are sequentially dry-etched using the resist pattern as a mask, thereby forming a three-layer film stack to serve as a bottom-gate electrode 20.

Next, on the substrate 10 with the bottom-gate electrode 20 formed thereon, a silicon nitride film with a thickness of from 300 to 400 nm is formed by plasma CVD (chemical vapor deposition), and then a silicon oxide film with a thickness of from 40 to 60 nm on the silicon nitride film. In this manner, the silicon oxide film is stacked on the silicon nitride film, whereby a gate insulating film 30 is formed. The hydrogen content of the silicon nitride film is low, similar to the hydrogen content of the first silicon nitride film 73 of the passivation film 70 to be described later.

On the gate insulating film 30, a semiconductor film 40a made of an In—Ga—Zn—O based semiconductor is formed by sputtering, as shown in FIG. 6(B). On the semiconductor film 40a, a resist pattern 48 is formed by photolithography, and the semiconductor film 40a is dry-etched using the resist pattern 48 as a mask, thereby forming a channel layer 40.

Above the substrate 10 with the channel layer 40 formed thereabove, a metal film 50a is formed by sequentially stacking a titanium film with a thickness of from 40 to 60 nm, an aluminum film with a thickness of from 150 to 250 nm, and another titanium film with a thickness of from 40 to 60 nm by means of sputtering, as shown in FIG. 6(C). On the upper titanium film, a resist pattern 58 is formed by photolithography, and the titanium film, the aluminum film, and the lower titanium film are sequentially dry-etched using the resist pattern 58 as a mask. As a result, a source conductor 50 is formed so as to extend leftward beyond the top-left portion of the channel layer 40, and also a drain conductor 60 is formed so as to extend rightward beyond the top-right portion of the channel layer 40. As a result, the channel layer 40 is exposed in a region between the source conductor 50 and the drain conductor 60.

As shown in FIG. 7(A), a passivation film 70 is to be formed by plasma CVD. First, on the exposed region of the channel layer 40, the source conductor 50, and the drain conductor 60, a silicon oxide film is formed to a thickness of from 200 to 400 nm. The flow rates of silane gas and nitrogen oxide (N₂O) gas required for forming the silicon oxide film are respectively from 200 to 400 sccm and from 500 to 1000 sccm. Next, on the silicon oxide film, a first silicon nitride film is formed to a thickness of from 100 to 200 nm. The flow rates of silane gas, ammonia (NH₃) gas, and nitrogen (N₂) gas required for forming the first silicon nitride film are respectively from 200 to 400 sccm, from 300 to 1000 sccm, and from 5000 to 10000 sccm. Further, on the first silicon nitride film, a second silicon nitride film is formed to a thickness of from 100 to 200 nm. The flow rates of silane gas, ammonia gas, and nitrogen gas required for forming the second silicon nitride film are respectively from 400 to 800 sccm, from 1000 to 2000 sccm, and from 5000 to 10000 sccm. In this manner, the second silicon nitride film is formed so as to have a high hydrogen content. Note that all of the films are formed under the conditions where RF power is from 1000 to 5000 W, substrate temperature is from 200 to 400° C., and pressure is from 500 to 3000 mTorr.

On the passivation film 70, an IZO film 80a is formed by sputtering, as shown in FIG. 7(B). On the IZO film 80a, a resist pattern (not shown) is formed by photolithography, and the IZO film 80a is dry-etched using the resist pattern as a mask. As a result, a top-gate electrode 80 is formed. In this manner, the TFT 100 according to the present embodiment is formed.

### <1.4 Effects>

In the present embodiment, the TFT has a double-gate structure with the channel layer 40 made of an oxide semiconductor, and uses the passivation film 70, which is a film stack obtained by stacking, sequentially from the side closest to the channel layer 40, the silicon oxide film 71, the first silicon nitride film 73, and the second silicon nitride film 74. In this case, the second silicon nitride film 74 farthest from the channel layer 40 is formed so as to have a higher hydrogen content than the first silicon nitride film 73 closer to the channel layer 40. Thus, it is rendered possible to inhibit the shifting of the threshold voltage of the TFT 100 resulting from hydrogen spreading in the channel layer 40, and at the same time, it is also rendered possible to diminish hysteresis and thereby inhibit the shifting of the threshold voltage caused by hysteresis.

In particular, the hydrogen content of the first silicon nitride film 73 is set at less than 5×10²¹ molecules/cm³, and the hydrogen content of the second silicon nitride film 74 is set at 5×10²¹ molecules/cm³ or higher, more preferably, 1×10²² molecules/cm³ or higher, whereby it is rendered possible to inhibit the shifting of the threshold voltage of the TFT 100 resulting from hydrogen spreading in the channel layer 40, and at the same time, it is also rendered possible to diminish hysteresis and thereby further inhibit the shifting of the threshold voltage caused by hysteresis.

Furthermore, in the case where the TFT 100 as above is used as a switching element for a pixel of a display device, the value of a signal voltage written to a liquid crystal capacitor connected to the TFT is kept substantially the same, so that constant image display quality is maintained. In addition, in the case where the TFT is used as a component of a peripheral circuit, such as a source or gate driver, of a display device, it is possible to reduce the malfunctioning of the peripheral circuit.

### <1.5 First Variant>

In the embodiment, the silicon nitride film 72 included in the passivation film 70 is formed of the two separate layers, i.e., the first silicon nitride film 73 and the second silicon nitride film 74. Further, either the first silicon nitride film 73 or the second silicon nitride film 74 may be composed of two separate layers, so that the passivation film 70 consists of a total of four layers, i.e., the silicon oxide film 71 and the three layers of silicon nitride film.

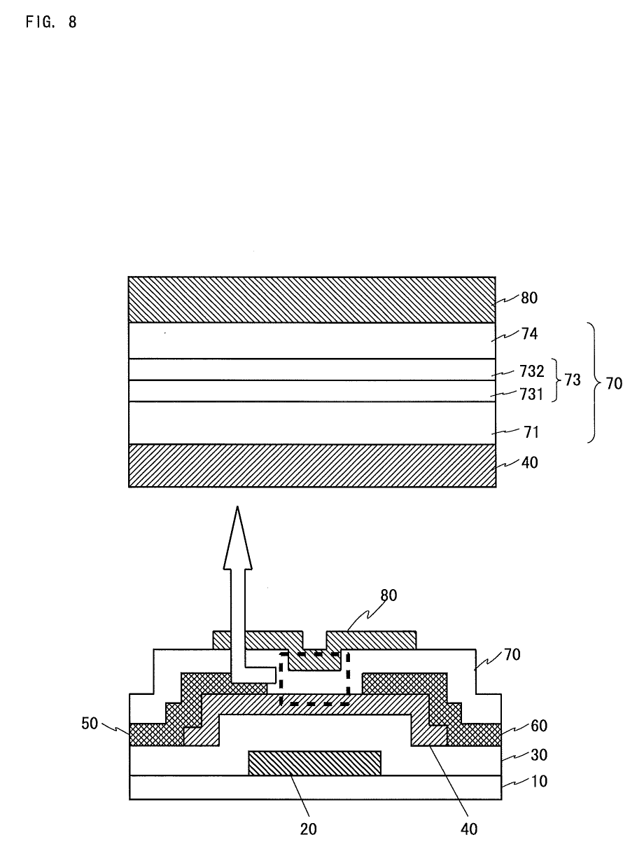

FIG. 8 provides an enlarged cross-sectional view of the passivation film 70 where the first silicon nitride film 73 shown in the enlarged cross-sectional view in FIG. 2 is composed of two separate layers. As shown in FIG. 8, the first silicon nitride film 73 is formed of a third silicon nitride film 731 proximal to the channel layer 40 and a fourth silicon nitride film 732 distal to the channel layer 40. In this case, the conditions under which the first silicon nitride film 73 is formed as described in the embodiment are changed as below. Each of the third and fourth silicon nitride films 731 and 732 has a thickness of 100 nm, and the flow rates of silane gas, ammonia (NH₃) gas, and nitrogen (N₂) gas required for forming the third silicon nitride film 731 proximal to the channel layer 40 are respectively from 200 to 300 sccm, from 300 to 500 sccm, and from 5000 to 7500 sccm. As a result, the third silicon nitride film 731 is formed so as to have a low hydrogen content. Next, the flow rates of silane gas, ammonia gas, and nitrogen gas required for forming the fourth silicon nitride film 732 are respectively from 300 to 400 sccm, from 500 to 1000 sccm, and from 7500 to 10000 sccm. As a result, the fourth silicon nitride film 732 is formed so as to have a higher hydrogen content than the third silicon nitride film 731. Note that both of the silicon nitride films 731 and 732 are formed under the conditions where RF power is from 1000 to 5000 W, substrate temperature is from 200 to 400° C., and pressure is from 500 to 3000 mTorr. As a result, the third silicon nitride film 731, the fourth silicon nitride film 732, and the second silicon nitride film 74 are sequentially formed on the silicon oxide film 71 in ascending order of hydrogen content.

In the present variant, the three silicon nitride films 731, 732, and 74 with different hydrogen contents are disposed from the channel layer 40 side in ascending order of hydrogen content, and therefore, the difference in hydrogen content between adjacent silicon nitride films is decreased. Thus, the hysteresis of the TFT can be diminished.

Note that instead of forming the first silicon nitride film 73 with two separate layers, the second silicon nitride film 74 may be formed of two separate layers. Moreover, either the first or second silicon nitride film 73 or 74, or both, may be formed of three or more separate layers.

### <1.6 Second Variant>

In the embodiment, the silicon nitride film 72 included in the passivation film 70 is formed of the two separate layers, i.e., the first silicon nitride film 73 and the second silicon nitride film 74. However, of the two silicon nitride films 73 and 74, only the silicon nitride film 74 proximal to the top-gate electrode 80 may be formed and included to form a silicon nitride film 75 whose hydrogen content continuously increases with the distance from the side proximal to the channel layer 40 toward the top-gate electrode 80 side.

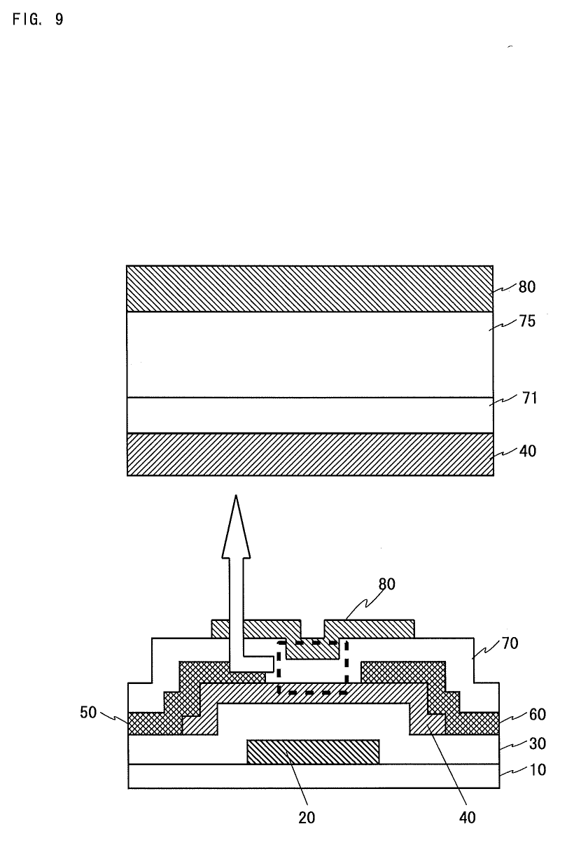

FIG. 9 provides cross-sectional views illustrating the structure of a passivation film including the silicon nitride film 75 whose hydrogen content changes continuously. As shown in FIG. 9, such a silicon nitride film 75 is formed, for example, under the conditions where the flow rate of silane gas is increased continuously from 200 sccm to 800 sccm over time, the flow rate of ammonia gas is increased continuously from 300 sccm to 2000 sccm over time, the flow rate of nitrogen gas is increased continuously from 500 sccm to 10000 sccm over time, RF power is from 1000 to 5000 W, substrate temperature is from 200 to 400° C., and pressure is from 500 to 3000 mTorr. Note that the flow rates of the gases are not limited to the foregoing so long as the flow rates can be adjusted so as to increase continuously over time.

In the present variant, the silicon nitride film 75 is formed such that hydrogen content increases continuously with the distance from the channel layer 40, whereby the hysteresis of the TFT can be diminished.

### <1.7 Third Variant>

In the present embodiment, while the IZO film 80a, which is included to form the top-gate electrode 80, is formed following the formation of the second silicon nitride film 74 with high hydrogen content, the second silicon nitride film 74 may be subjected to hydrogen plasma treatment on the surface before the formation of the IZO film 80a. In this case, by the hydrogen plasma treatment, hydrogen content increases around the surface of the second silicon nitride film 74, i.e., around the surface farthest from the channel layer 40. Accordingly, the hydrogen plasma treatment is preferably performed under the conditions where hydrogen does not reach deep into the second silicon nitride film 74 (i.e., a deep position close to the silicon nitride film 73). Therefore, the hydrogen plasma treatment is preferably performed under the conditions where values, in particular, for the flow rate of hydrogen (H₂) gas, RF power, and treatment time are not excessively high.

In this variant, hydrogen content can be increased around the surface of the second silicon nitride film 74 farthest from the channel layer 40, whereby the hysteresis of the TFT can be diminished.

### <1.8 Fourth Variant>

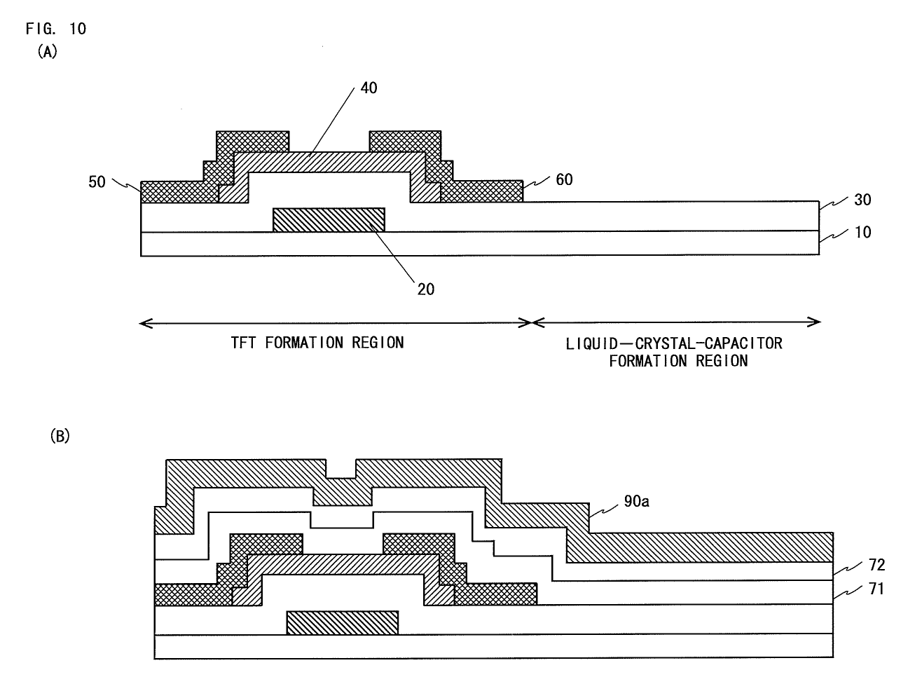

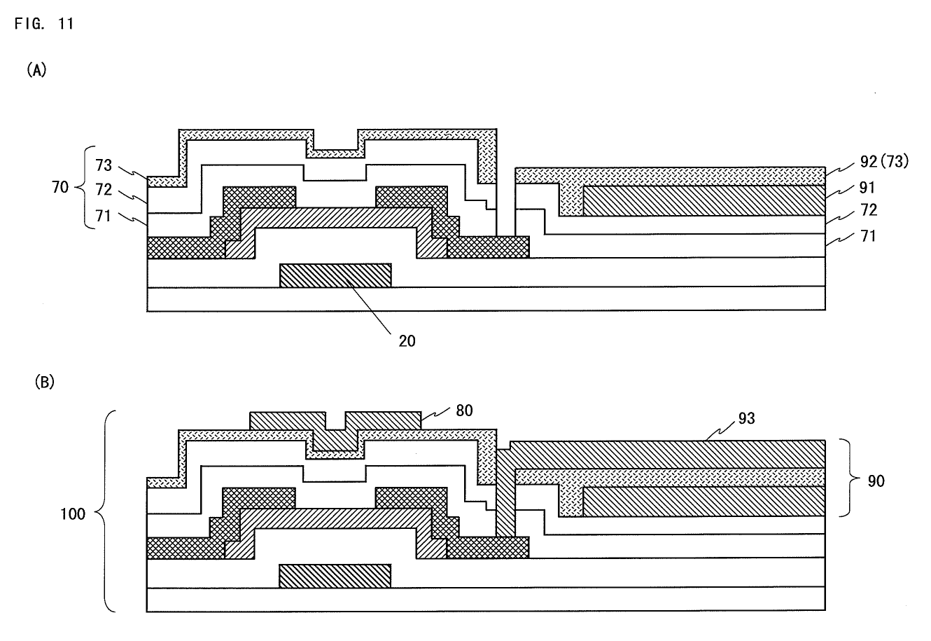

FIGS. 10(A), 10(B), 11(A), and 11(B) are views illustrating the process for manufacturing a TFT with a liquid crystal capacitor in a fourth variant of the present embodiment. First, there is provided a substrate 10, including a TFT formation region in which to form the TFT 100 and a liquid-crystal-capacitor formation region in which to form the liquid crystal capacitor 90 connected to the TFT, as shown in 10(A) of the figure. In the TFT formation region, a bottom-gate electrode 20, a gate insulating film 30, a channel layer 40, a source conductor 50, and a drain conductor 60 are sequentially formed over the substrate 10 in the same manner as in the case shown in FIGS. 6(A) to 6(C). In the liquid-crystal-capacitor formation region, only the gate insulating film 30 is formed on the substrate 10.

Next, both in the TFT formation region and the liquid-crystal-capacitor formation region, a silicon oxide film 71 and a first silicon nitride film 73, which are constituents of a passivation film 70, are sequentially formed by plasma CVD, as shown in FIG. 10(B). Further, on the first silicon nitride film 73, an IZO film 90a is formed.

In the liquid-crystal-capacitor formation region, a resist pattern (not shown) is formed by photolithography, and the IZO film is wet-etched using the resist pattern as a mask, thereby forming a common electrode 91 for the liquid crystal capacitor 90, as shown in FIG. 11(A). In this case, the channel layer 40 sandwiched between the source conductor 50 and the drain conductor 60 in the TFT formation region is covered by the silicon oxide film 71 and the first silicon nitride film 73, and therefore, the surface of the channel layer 40 is not etched at the time of the wet etching for forming the common electrode 91. Further, a second silicon nitride film 74 is formed by plasma CVD. The second silicon nitride film 74 is formed as a part of the passivation film 70 in the TFT 100 and also extends over the common electrode 91. The second silicon nitride film 74 has a thickness of from 100 to 200 nm, and therefore is used in part as an auxiliary capacitance layer 92 of the liquid crystal capacitor 90.

An IZO film 80a is formed by sputtering and then dry-etched using a resist pattern (not shown), which is formed by photolithography, as a mask, as shown in FIG. 11(B). As a result, a top-gate electrode 80 is formed in the TFT formation region, and a pixel electrode 93 is formed in the liquid-crystal-capacitor formation region. In this manner, the TFT 100 and the liquid crystal capacitor 90 connected thereto can be simultaneously formed on the substrate 10.

In the present embodiment, when the common electrode 91 is formed by wet etching, the surface of the channel layer 40 is not etched because the surface is covered by the silicon oxide film 71 and the first silicon nitride film 73.

Furthermore, since the second silicon nitride film 74, which is a part of the passivation film 70 in the TFT 100, and the auxiliary capacitance layer 92 of the liquid crystal capacitor 90 can be formed simultaneously, the manufacturing process can be simplified. Note that the liquid crystal capacitor 90, the common electrode 91, the auxiliary capacitance layer 92, and the pixel electrode 93 will also be referred to as the “capacitance element”, the “first electrode”, the “insulating layer”, and the “second electrode”, respectively.

### 2. Second Embodiment

The structure of a TFT according to a second embodiment of the present invention, along with a method for manufacturing the TFT, will be described with reference to the drawings.

### <2.1 Structure of the TFT>

The basic structure of the TFT according to the present embodiment is the same as the structure of the TFT 100 shown in FIGS. 1(A) and 1(B), and therefore, features different from those of the TFT 100 according to the first embodiment will be mainly described with reference to FIGS. 1(A) and 1(B) while the same features will be described briefly.

As shown in FIGS. 1(A) and 1(B), there is a bottom-gate electrode 20 formed on a substrate 10 such as a glass substrate. On the bottom-gate electrode 20, a gate insulating film 30 is formed. Unlike in the first embodiment, the gate insulating film 30 is a film stack consisting of a total of three layers, including two silicon nitride films with different hydrogen contents and a silicon oxide film stacked on the silicon nitride films. The two silicon nitride films are a second silicon nitride film formed on the outermost side (i.e., the side closest to the bottom-gate electrode 20) and a first silicon nitride film formed on the second silicon nitride film, and the second silicon nitride film is formed so as to have a higher hydrogen content than the first silicon nitride film. That is, the second silicon nitride film with high hydrogen content is provided in a position away from a channel layer 40.

As for the thickness of each constituting layer of the gate insulating film 30, for example, the second silicon nitride film has a thickness of from 100 to 200 nm, the first silicon nitride film has a thickness of from 200 to 400 nm, and the silicon oxide film has a thickness of from 200 to 400 nm. In this manner, the gate insulating film 30 of the present embodiment is structured so as to have a linearly symmetric relationship with a passivation film 70, as provided in the first embodiment, with respect to the channel layer 40, which is the axis of symmetry. The hydrogen contents of the first and second silicon nitride films will be described later. Note that the first silicon nitride film is thicker than the first silicon nitride film 73, which is included in the passivation film 70 of the first embodiment and has a thickness of from 100 to 200 nm, and the reason for this is to diminish parasitic capacitance created between the bottom-gate electrode 20 and a source conductor 50 or a drain conductor 60. Moreover, instead of forming the first and second silicon nitride films, first and second silicon oxynitride film (SiONx) films may be formed.

Formed on the gate insulating film 30 is the channel layer 40 made of an oxide semiconductor and provided in the shape of a rectangle stretching beyond opposite sides of the bottom-gate electrode 20 in the right-left direction in FIG. 1(B). Moreover, the source conductor 50 and the drain conductor 60 are formed in the shape of rectangles extending from opposite sides of the channel layer 40 in the channel-length direction so as to be away from each other (in the right-left direction in FIG. 1(B)).

Formed in a region including the source conductor 50, the drain conductor 60, and a portion of the channel layer 40 that is not covered by these conductors is the passivation film 70. The passivation film 70 is a film stack consisting of a silicon oxide film and a silicon nitride film formed thereon. The silicon oxide film has a thickness of from 250 to 350 nm, and the silicon nitride film has a thickness of from 100 to 200 nm. Moreover, the hydrogen content of the silicon nitride film is low, similar to the hydrogen content of the first silicon nitride film in the gate insulating film 30. Formed on the passivation film 70 is a top-gate electrode 80, which is made of IZO and positioned above the channel layer 40 sandwiched between the source conductor 50 and the drain conductor 60.

### <2.2 Hydrogen Content in the Gate Insulating Film>

In the gate insulating film 30 in the present embodiment, as in the case of the passivation film 70 in the first embodiment, the hydrogen content in the silicon nitride film is preferably low because the lower the hydrogen content is, the less the shifting of the threshold voltage of the TFT is. However, in contrast, if the hydrogen content is excessively low, there is a problem where hysteresis becomes significant, as shown in FIG. 14.

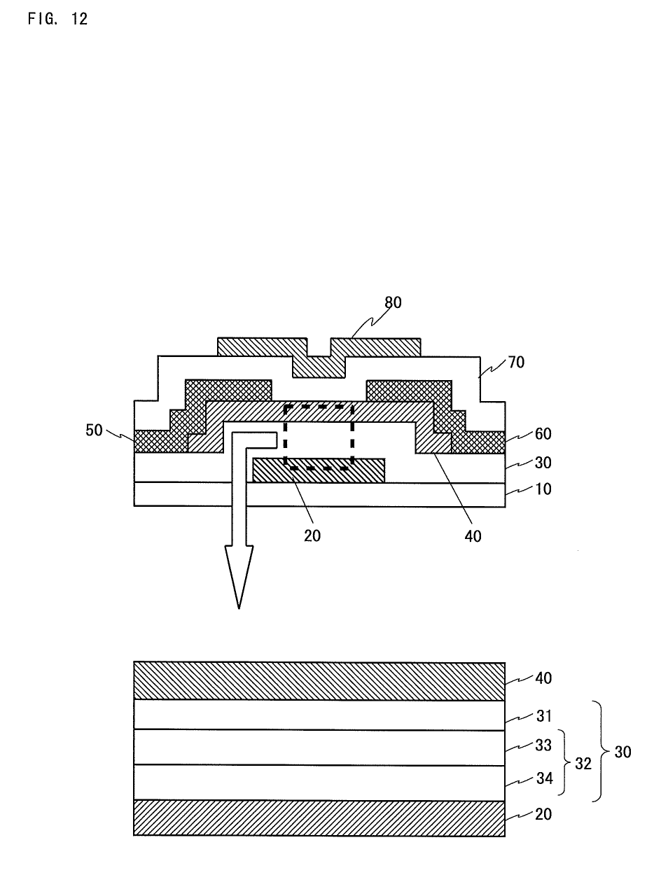

Therefore, the hydrogen content in the silicon nitride included in the gate insulating film is set as below. FIG. 12 provides an enlarged cross-sectional view illustrating the structure of the gate insulating film 30 in the present embodiment. Specifically, the enlarged cross-sectional view shown in FIG. 12 corresponds to a portion of the TFT depicted within a rectangle in the lower part of FIG. 12. The gate insulating film 30 sandwiched between the bottom-gate electrode 20 and the channel layer 40 is a film stack in which a silicon nitride film 32 and a silicon oxide film 31 are formed sequentially from the bottom-gate electrode 20 side, as shown in FIG. 12. Moreover, the silicon nitride film 32 consists of a first silicon nitride film 33 with low hydrogen content and a second silicon nitride film 34 with high hydrogen content, the first silicon nitride film 33 is formed on the channel layer 40 side, and the second silicon nitride film 34 is formed on the outside with respect to the first silicon nitride film 33. Note that the silicon nitride film 32 will also be referred to herein as the “nitride insulating region”.

In the present embodiment, as in the first embodiment, the hydrogen content of the first silicon nitride film 33 is determined on the basis of the relationship shown in FIG. 3 between the amount of hydrogen emission from the silicon nitride film and the threshold-voltage shift amount of the TFT. To reduce the threshold-voltage shift amount, it is necessary to reduce the hydrogen content of the silicon nitride film. From FIG. 3, it can be appreciated that, to reduce the threshold-voltage shift amount ΔVth of the TFT to 2V or less, it is necessary to reduce the amount of hydrogen emission from the first silicon nitride film 33 to less than 5×10²¹ molecules/cm³. As a result, the amount of hydrogen spreading from the first silicon nitride film 33 proximal to the channel layer 40 into the channel layer 40 through the silicon oxide film 31 is reduced. On the other hand, the amount of hydrogen emission from the first silicon nitride film 33 is required to be at least 5×10²⁰ molecules/cm³. The reason for this is that when the amount of hydrogen emission is less than 5×10²⁰ molecules/cm³, the threshold voltage varies greatly among TFTs formed on the substrate 10.

Furthermore, the hydrogen content in the second silicon nitride film 34 is determined on the basis of the relationship shown in FIG. 4 between the amount of hydrogen emission from the silicon nitride film and the magnitude of hysteresis of the TFT. It can be appreciated that, to keep the magnitude of hysteresis at 4V or less, it is simply required to increase the hydrogen content of the silicon nitride film. Accordingly, on the basis of FIG. 4, the amount of hydrogen emission from the second silicon nitride film 34 is set at 5×10²¹ molecules/cm³ or more. In addition, the magnitude of hysteresis is preferably reduced to 2V or less, and in such a case, the amount of hydrogen emission from the second silicon nitride film 34 is set at 1×10²² molecules/cm³ or more. As a result, as in the case of the TFT 100 according to the first embodiment, the hysteresis of the TFT according to the present embodiment is lessened significantly. On the other hand, the amount of hydrogen emission from the second silicon nitride film 34 is required to be 5×10²² molecules/cm³ or less. The reason for this is that when the amount of hydrogen emission is more than 5×10²² molecules/cm³, hydrogen spreads in the silicon nitride film 34 with low hydrogen content, whereby carriers are generated, with the result that the threshold voltage of the TFT is shifted.

In this manner, the silicon nitride film in the gate insulating film is formed of two separate layers, such that the second silicon nitride film 34 distal to the channel layer has a higher hydrogen content than the first silicon nitride film 33 proximal to the channel layer, whereby hysteresis can be diminished. In addition, the hydrogen content of the first silicon nitride film is set at less than 5×10²¹ molecules/cm³, and the hydrogen content of the second silicon nitride film is set at 5×10²¹ molecules/cm³ or higher, more preferably, 1×10²² molecules/cm³ or higher, whereby the hysteresis of the TFT can be further diminished.

### <2.3 Method for Manufacturing the TFT>

Numerous manufacturing steps included in the method for manufacturing the TFT are the same as the manufacturing steps of the method for manufacturing the TFT 100 according to the first embodiment shown in FIGS. 6(A) to 6(C) and 7(A) to 7(C). Therefore, referring to the cross-sectional views in the figures, different manufacturing steps will be described mainly while the same process manufacturing as the manufacturing steps for the TFT 100 according to the first embodiment will be described briefly.

A film stack consisting of three layers, which are a titanium film, an aluminum film, and another titanium film, is dry-etched, thereby forming a bottom-gate electrode 20 on a substrate 10. Next, on the substrate 10 with the bottom-gate electrode 20 formed thereon, a gate insulating film 30 is formed by plasma CVD. As for the gate insulating film 30, a second silicon nitride film with a thickness of from 100 to 200 nm is initially formed. The flow rates of silane gas, ammonia gas, and nitrogen gas required for forming the second silicon nitride film are respectively from 400 to 800 sccm, from 1000 to 2000 sccm, and from 5000 to 10000 sccm. As a result, the second silicon nitride film is formed so as to have a high hydrogen content.

Next, a first silicon nitride film is formed to a thickness of from 200 to 400 nm. The flow rates of silane gas, ammonia gas, and nitrogen gas required for forming the first silicon nitride film are respectively from 200 to 400 sccm, from 300 to 1000 sccm, and from 5000 to 10000 sccm. As a result, the first silicon nitride film is formed so as to have a low hydrogen content.

Furthermore, on the first silicon nitride film, a silicon oxide film is formed to a thickness of from 200 to 400 nm. The flow rates of silane gas and nitrogen oxide (N₂O) gas required for forming the silicon oxide film are respectively from 200 to 400 sccm and from 500 to 1000 sccm. Note that both films are formed under the conditions where RF power is from 1000 to 5000W, substrate temperature is from 200 to 400° C., and pressure is from 500 to 3000 mTorr.

Next, on the gate insulating film 30, a semiconductor film 40a made of an oxide semiconductor is formed by sputtering and then dry-etched to form a channel layer 40. Over the substrate 10 with the channel layer 40 formed thereabove, a film stack consisting of a titanium film, an aluminum film, and another titanium film is formed by sputtering and then dry-etched. As a result, a source conductor 50 and a drain conductor 60 are formed.

A passivation film 70 is to be formed by plasma CVD. First, a silicon oxide film is formed to a thickness of from 200 to 400 nm so as to cover an exposed region of the channel layer 40, the source conductor 50, and the drain conductor 60. On the silicon oxide film, a silicon nitride film is formed to a thickness of from 100 to 200 nm. The silicon nitride film is formed under the same conditions as the first silicon nitride film included in the gate insulating film 30, except for thickness. Accordingly, the hydrogen content of the silicon nitride film is less than 5×10²¹ molecules/cm³, which is low, similar to the hydrogen content of the first silicon nitride film.

Next, on the passivation film 70, an IZO film 80a is formed by sputtering and then dry-etched. As a result, a top-gate electrode 80 is formed. In this manner, the TFT according to the present embodiment is formed.

### <2.4 Effects>

In the present embodiment, the TFT has a double-gate structure with the channel layer 40 made of an oxide semiconductor, and uses the gate insulating film 30, which is a film stack obtained by stacking, sequentially from the bottom-gate electrode 20 side toward the channel layer 40 side, the second silicon nitride film 74, the first silicon nitride film 33, and the silicon oxide film 31. In this case, the first silicon nitride film 33 proximal to the channel layer 40 and the second silicon nitride film 34 distal to the channel layer 40 are formed such that the second silicon nitride film 34 has a higher hydrogen content than the first silicon nitride film 33. Thus, as in the first embodiment, it is rendered possible to inhibit the shifting of the threshold voltage of the TFT 100 resulting from hydrogen spreading in the channel layer 40, and at the same time, it is also rendered possible to diminish hysteresis and thereby inhibit the shifting of the threshold voltage caused by hysteresis.

Furthermore, the hydrogen content of the first silicon nitride film 33 in the gate insulating film 30 is set at less than 5×10²¹ molecules/cm³, and the hydrogen content of the second silicon nitride film 34 is set at 5×10²¹ molecules/cm³ or higher, more preferably, 1×10²² molecules/cm³ or higher, whereby it is rendered possible to inhibit the shifting of the threshold voltage of the TFT 100 resulting from hydrogen spreading in the channel layer 40, and at the same time, it is also rendered possible to diminish hysteresis and thereby further inhibit the shifting of the threshold voltage caused by hysteresis.

Furthermore, in the case where the TFT as above is used as a switching element for a pixel formed in a display portion of a display device, the value of a signal voltage written to a liquid crystal capacitor connected to the TFT is kept substantially the same, so that constant image display quality is maintained. In addition, in the case where the TFT is used as a component of a peripheral circuit, such as a source or gate driver, of a liquid crystal display device, it is possible to reduce the malfunctioning of the peripheral circuit.

### <2.5 First Variant>

The variant structures of the passivation film 70 described in the first and second variants of the first embodiment can be applied to the structure of the gate insulating film 30 in the present embodiment without modification. Accordingly, such variants will be described briefly.

Either the first silicon nitride film 33 or the second silicon nitride film 34, or both, in the gate insulating film 30 may consist of two or more separate layers with different hydrogen contents. As a result, the gate insulating film 30 includes at least three silicon nitride films. Moreover, the gate insulating film 30 may include only one silicon nitride film which is formed such that hydrogen content continuously increases with the distance from the side proximal to the channel layer 40 toward the bottom-gate electrode 20. In either case, hysteresis can be diminished as in the case of the first embodiment.

### <2.6 Second Variant>

In the present embodiment, while the first silicon nitride film 33 of the gate insulating film 30 is formed following the formation of the second silicon nitride film 34, the second silicon nitride film 34 may be subjected to hydrogen plasma treatment on the surface before the formation of the first silicon nitride film 33. In this case, by the hydrogen plasma treatment, the hydrogen content of the second silicon nitride film 34 increases around the surface proximal to the bottom-gate electrode 20, i.e., around the position farthest from the channel layer 40. Accordingly, by the hydrogen plasma treatment, hydrogen reaches deep down from the surface of the second silicon nitride film 34, unlike in the third variant of the first embodiment. Such hydrogen plasma treatment is performed, for example, under the conditions where the flow rate of hydrogen gas is from 500 to 1000 sccm, RF power is from 200 to 1000 W, treatment time is from 30 to 60 seconds, substrate temperature is from 200 to 400° C., and pressure is from 500 to 3000 mTorr.

In this variant, the hydrogen content in the second silicon nitride film 34 of the gate insulating film 30 can be increased around the position farther from the channel layer 40, resulting in a diminished hysteresis of the TFT.

### 3. Third Embodiment

The structure of a TFT according to a third embodiment of the present invention, along with a method for manufacturing the TFT, will be described with reference to the drawings.

### <3.1 Structure of the TFT>

The basic structure of the TFT according to the present embodiment is the same as the structure of the TFT 100 shown in FIG. 1, and therefore, features different from those of the TFT 100 according to the first embodiment will be mainly described with reference to FIGS. 1(A) and 1(B) while the same features will be described briefly.

As shown in FIGS. 1(A) and 1(B), the bottom-gate electrode 20 is formed on the substrate 10 such as a glass substrate. In the TFT according to the present embodiment, unlike in the TFT 100 according to the first embodiment, the gate insulating film 30 includes a silicon nitride film 32 consisting of two layers with different hydrogen contents, as in the case of the passivation film 70. More specifically, the silicon nitride film 32 consists of two separate layers, which are a first silicon nitride film 33 with low hydrogen content formed on the side proximal to the channel layer 40, and a second silicon nitride film 34 with high hydrogen content formed on the side distal to the channel layer 40. In this manner, in the gate insulating film 30, as in the case of the passivation film 70, the second silicon nitride film 34 distal to the channel layer 40 has a higher hydrogen content than the first silicon nitride film 33 proximal to the channel layer 40, whereby the hysteresis of the TFT can be diminished.

### <3.2 Method for Manufacturing the TFT>

Numerous manufacturing steps included in the method for manufacturing the TFT are the same as the manufacturing steps of the method for manufacturing the TFT 100 according to the first embodiment shown in FIGS. 6(A) to 6(C) and 7(A) to 7(C). Therefore, referring to the cross-sectional views in the figures, different manufacturing steps will be described mainly while the same manufacturing steps as the manufacturing steps for the TFT 100 according to the first embodiment will be described briefly.

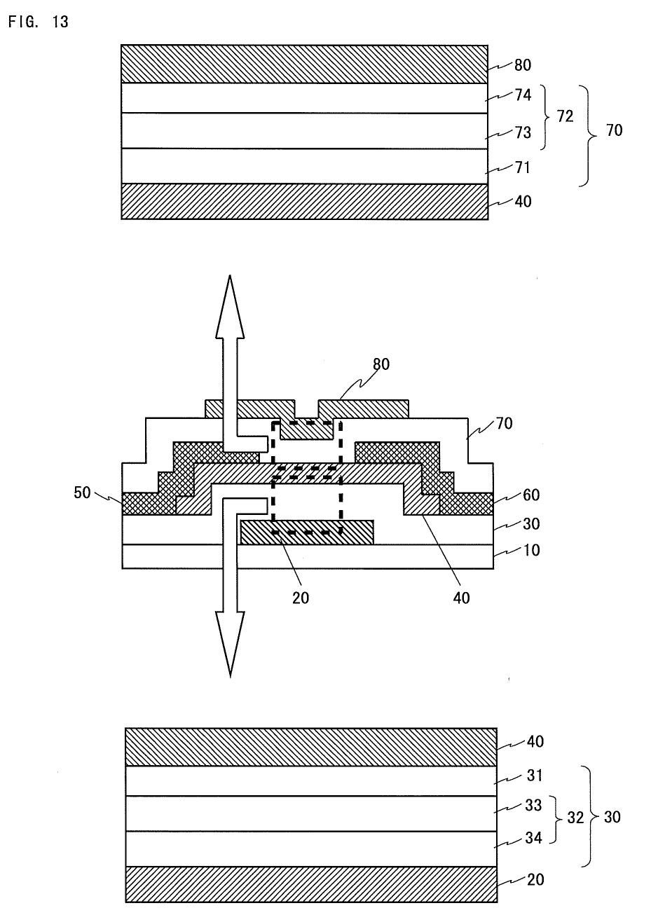

The TFT manufacturing method according to the present embodiment differs from the manufacturing process shown in FIGS. 6(A) to 6(C) and 7(A) to 7(C) only in the process for forming the gate insulating film 30. In the present embodiment, the gate insulating film 30 includes the two silicon nitride films 33 and 34 with different hydrogen contents, as in the case of the passivation film 70 in the first embodiment. Accordingly, as shown in FIGS. 6(A) and 13, the second silicon nitride film 34 with high hydrogen content is initially formed so as to cover the bottom-gate electrode 20, the first silicon nitride film 33 with low hydrogen content is then formed on the second silicon nitride film 34, and further, the silicon oxide film 31 is formed on the first silicon nitride film 33, resulting in the gate insulating film 30. Note that the manufacturing steps of forming the first and second silicon nitride films 33 and 34 are the same as the manufacturing step for the gate insulating film described in detail in conjunction with the TFT manufacturing method according to the second embodiment, and therefore, any descriptions thereof will be omitted.

### <3.3 Effects>

In the present embodiment, the TFT that has a double-gate structure with the channel layer 40 made of an oxide semiconductor uses the gate insulating film 30 and the passivation film 70, which are film stacks respectively including the silicon nitride films 32 and 72, each consisting of two layers with different hydrogen contents, and the film stacks are obtained by stacking, sequentially from the side farthest from the channel layer 40 toward the closest side, the second silicon nitride film 34 or 74 with high hydrogen content, the first silicon nitride film 33 or 73 with low hydrogen content, and the silicon oxide film 31 or 71. As a result, in the present embodiment, as in the first and second embodiments, the TFT has a diminished hysteresis as represented by the Vg-Id characteristics shown in FIG. 5. Thus, the present embodiment likewise renders it possible to inhibit the shifting of the threshold voltage of the TFT 100 resulting from hydrogen spreading in the channel layer 40, and at the same time, also renders it possible to reduce hysteresis and thereby inhibit the shifting of the threshold voltage caused by hysteresis.

Furthermore, the hydrogen contents of the first silicon nitride films 33 and 73 are set at less than 5×10²¹ molecules/cm³, and the hydrogen contents of the second silicon nitride films 34 and 74 are set at 5×10²¹ molecules/cm³ or higher, more preferably, 1×10²² molecules/cm³ or higher. Thus, it is rendered possible to inhibit the shifting of the threshold voltage of the TFT 100 resulting from hydrogen spreading in the channel layer 40, and at the same time, it is also rendered possible to reduce hysteresis and thereby further inhibit the shifting of the threshold voltage caused by hysteresis. Note that the lower limit of the hydrogen contents of the first silicon nitride films 33 and 73 and the upper limit of the hydrogen contents of the second silicon nitride films 34 and 74 are the same as the lower and upper limits described in the first and second embodiments, and therefore, any descriptions thereof will be omitted.

Furthermore, in the case where the TFT as above is used as a switching element for a pixel of a display device, the value of a signal voltage written to a liquid crystal capacitor connected to the TFT is kept substantially the same, so that constant image display quality is maintained. In addition, in the case where the TFT is used as a component of a peripheral circuit, such as a source or gate driver, of a display device, it is possible to reduce the malfunctioning of the peripheral circuit.

### <3.4 Variants>

The first through third variants described in the first embodiment can be applied not only to the structure of the passivation film 70 in the present embodiment but also to the structure of the gate insulating film 30. Accordingly, the structure described in each of the variants can be applied to either the passivation film 70 or the gate insulating film 30, or both.

Furthermore, as in the fourth variant of the first embodiment, the second silicon nitride film 74 included in the passivation film 70 is utilized in part as the auxiliary capacitance layer 92 of the liquid crystal capacitor, whereby the manufacturing process in which the TFT and the liquid crystal capacitor are formed simultaneously can be simplified.

### INDUSTRIAL APPLICABILITY

The present invention is suitably used for drive TFTs included in source and gate drivers of display devices as well as for pixel TFTs serving as switching elements of pixels.

### DESCRIPTION OF THE REFERENCE CHARACTERS

20 bottom-gate electrode

30 gate insulating film

31 silicon oxide film (oxide insulating film)

32 silicon nitride film (nitride insulating region)

33 first silicon nitride film (first nitride insulating film)

34 second silicon nitride film (second nitride insulating film)

40 channel layer

50 source conductor

60 drain conductor

70 passivation film (protective film)

71 silicon oxide film (oxide insulating film)

72 silicon nitride film (nitride insulating region)

73 first silicon nitride film (first nitride insulating film)

74 second silicon nitride film (second nitride insulating film)

75 silicon nitride film

80 top-gate electrode

90 liquid crystal capacitor (capacitance element)

91 common electrode (first electrode)

92 auxiliary capacitance layer (insulating layer)

93 pixel electrode (second electrode)

100 TFT (semiconductor device)

1. A semiconductor device comprising:
a bottom-gate electrode formed on a substrate;
a gate insulating film formed on the bottom-gate electrode;
a channel layer overlying a part of the bottom-gate electrode with the gate insulating film intervening therebetween;
source and drain conductors electrically connected to the channel layer;
a protective film formed on the channel layer; and
a top-gate electrode formed on the protective film so as to be positioned opposite the bottom-gate electrode, wherein,
either the gate insulating film or the protective film, or both, includes a nitride insulating region made of one or more nitride insulating films, and
the nitride insulating region is formed such that hydrogen content increases with the distance from the channel layer.

2. The semiconductor device according to claim 1, wherein the nitride insulating region included in the protective film is a film stack obtained by stacking at least two of the nitride insulating films containing hydrogen such that the hydrogen contained in the nitride insulating films increases with the distance from the channel layer.

3. The semiconductor device according to claim 1, wherein the nitride insulating region included in the protective film includes a single-layer nitride insulating film containing hydrogen and being formed such that the contained hydrogen increases with the distance from the channel layer.

4. The semiconductor device according to claim 2, wherein the protective film further includes an oxide insulating film disposed between the channel layer and the film stack or the single-layer nitride insulating film.

5. The semiconductor device according to claim 1, wherein the nitride insulating region included in the gate insulating film is a film stack obtained by stacking at least two of the nitride insulating films containing hydrogen such that the hydrogen contained in the nitride insulating films increases with the distance from the channel layer.

6. The semiconductor device according to claim 1, wherein the nitride insulating region included in the gate insulating film includes a single-layer nitride insulating film containing hydrogen and being formed such that the contained hydrogen increases with the distance from the channel layer.

7. The semiconductor device according to claim 5, wherein the gate insulating film further includes an oxide insulating film disposed between the channel layer and the film stack or the single-layer nitride insulating film.

8. The semiconductor device according to claim 1, wherein the channel layer includes an oxide semiconductor.

9. The semiconductor device according to claim 8, wherein the oxide semiconductor is indium gallium zinc oxide.

10. The semiconductor device according to claim 9, wherein the indium gallium zinc oxide is crystalline.

11. The semiconductor device according to claim 2, wherein the nitride insulating film is a silicon nitride film or a silicon oxynitride film.

12. The semiconductor device according to claim 4, wherein the oxide insulating film is a silicon oxide film.

13. The semiconductor device according to claim 2, wherein the nitride insulating region is a stack of a first silicon nitride film disposed on a side proximal to the channel layer and a second silicon nitride film disposed on a side distal to the channel layer and emitting more hydrogen molecules than the first silicon nitride film.

14. The semiconductor device according to claim 13, wherein the amount of hydrogen molecule emission as measured by thermal desorption spectroscopy is less than 5×10²¹ molecules/cm³ for the first silicon nitride film and 5×10²¹ molecules/cm³ or more for the second silicon nitride film.

15. The semiconductor device according to claim 1, further comprising a capacitance element including a first electrode, a second electrode electrically connected to the drain conductor, and an insulating layer provided between the first and second electrodes, wherein,
the nitride insulating region included in the protective film is a stack of a first silicon nitride film disposed on a side proximal to the channel layer and a second silicon nitride film disposed on a side distal to the channel layer and containing more hydrogen than the first silicon nitride film, and
the insulating layer is a film simultaneously formed with the second silicon nitride film included in the protective film.

16. A method for manufacturing a semiconductor device including a bottom-gate electrode formed on a substrate, a gate insulating film formed on the bottom-gate electrode, a channel layer overlying a part of the bottom-gate electrode with the gate insulating film intervening therebetween, source and drain conductors electrically connected to the channel layer, a protective film formed on the channel layer, and a top-gate electrode formed on the protective film so as to be positioned opposite the bottom-gate electrode, wherein,
the gate insulating film includes first and second silicon nitride films containing hydrogen, the first silicon nitride film being formed on the second silicon nitride film and containing less hydrogen than the second silicon nitride film, and
the method comprises a plasma treatment step for performing hydrogen plasma treatment on a surface of the second silicon nitride film after the formation of the second silicon nitride film but before the formation of the first silicon nitride film.

17. A method for manufacturing a semiconductor device including a bottom-gate electrode formed on a substrate, a gate insulating film formed on the bottom-gate electrode, a channel layer overlying a part of the bottom-gate electrode with the gate insulating film intervening therebetween, source and drain conductors electrically connected to the channel layer, a protective film formed on the channel layer, and a top-gate electrode formed on the protective film so as to be positioned opposite the bottom-gate electrode, wherein,
the protective film includes a first silicon nitride film containing hydrogen and a second silicon nitride film formed on the first silicon nitride film and containing more hydrogen than the first silicon nitride film, and
the method comprises a plasma treatment step for performing hydrogen plasma treatment on a surface of the second silicon nitride film after the formation of the second silicon nitride film but before the formation of the top-gate electrode.
